(19) United States
(12) Patent Application Publication
(10) Pub. No.: US 2008/0013753 A1
(43) Pub. Date: Jan. 17, 2008

(54) ENVIRONMENTALLY CONTROLLED FREQUENCY RESPONSE MODIFICATION FOR LONG RANGE HAILING SYSTEM

(75) Inventors: Terry J. Conrad, Poulsbo, WA (US); Michael E. Spencer, Green Cove Springs, FL (US)

Correspondence Address: BLACK LOWE & GRAHAM, PLLC, 701 FIFTH AVENUE, SUITE 4800, SEATTLE, WA, 98104, US

(73) Assignee: CONQUEST INNOVATIONS, LLC, Kingston, WA (US)

(21) Appl. No.: 11/775,796

(22) Filed: Jul. 10, 2007

Related U.S. Application Data
(60) Provisional application No. 60/807,053, filed on Jul. 11, 2006.

(51) Int. Cl. H03G 5/00

(52) U.S. Cl. 381/103; 381/98

(57) ABSTRACT

Systems and methods for altering audio for more effective delivery to long range targets. An example of the present invention includes a speaker coupled to a processor and one or more sensors suitable for sensing environmental conditions such as temperature and humidity. The processor reads the output of the sensors and compensates for frequency dependent attenuation likely to occur at the sensed environmental condition. In one embodiment, the user specifies a range that the sound is to travel and an equalization table compensating for attenuation at the desired range is selected according to the user input.

### PRIORITY CLAIM

This application claims the benefit of U.S. Provisional Application Ser. No. 60/807,053 filed Jul. 11, 2006.

### FIELD OF THE INVENTION

This invention relates generally to sound amplification systems and, more specifically, to long range hailing systems.

### BACKGROUND OF THE INVENTION

The voice intelligibility of an audio public address (PA) system is highly dependent on its frequency response. For example, a deficiency in high frequency response above about 2 kHz will result in the listener having difficulty discerning consonants, such as the difference between the sounds of “f” and “s”; or between the sounds of “c”, “Z”, and “v.” A lack of smooth frequency response throughout the mid-range region, around 400-2000 Hz, can cause difficulties in discerning vowels and certain words.

In the case of a system designed to be used at very long ranges, such as more than 500 yards, another effect becomes important. That is, that the propagation of sound through air is highly affected by temperature and by relative humidity (RH), and the propagation loss (called “loss by absorption”) is frequency dependent at any given combination of temperature and RH.

Higher frequencies have a higher rate of loss per unit of distance than do lower frequencies, and the loss further depends on temperature and RH. There is not a linear function for describing loss versus frequency, temperature and RH. These effects must be considered holistically in a system in order to provide maximum intelligibility at long distances, such as in police, fire, military and other safety-related applications. For example, the user of a system in an emergency cannot take the time to optimize the system's frequency response for his environment and the range at which he intends a loud-hailing or P.A. system to transmit.

Accordingly, it would be advancement in the art to provide a system for readily compensating for frequency dependent attenuation losses in long range hailing systems.

### SUMMARY OF THE INVENTION

The present invention includes a speaker coupled to a processor and one or more sensors suitable for sensing environmental conditions such as temperature and humidity. The processor reads the output of the sensors and selects one of a plurality of equalization tables suitable for compensating for frequency dependent attenuation likely to occur at the sensed environmental condition. In one embodiment, the user specifies a range that the sound is to travel and an equalization table compensating for attenuation at the desired range is selected according to the user input.

### BRIEF DESCRIPTION OF THE DRAWINGS

Preferred and alternative embodiments of the present invention are described in detail below with reference to the following drawings:

FIG. 1 is a schematic block diagram of a sound system compensating for environmental conditions;

FIG. 2 is a graph illustrating frequency dependent attenuation in air for various temperatures; and

FIG. 3 is a process flow diagram of a method for using the sound system of FIG. 1.

### DETAILED DESCRIPTION OF THE PREFERRED EMBODIMENT

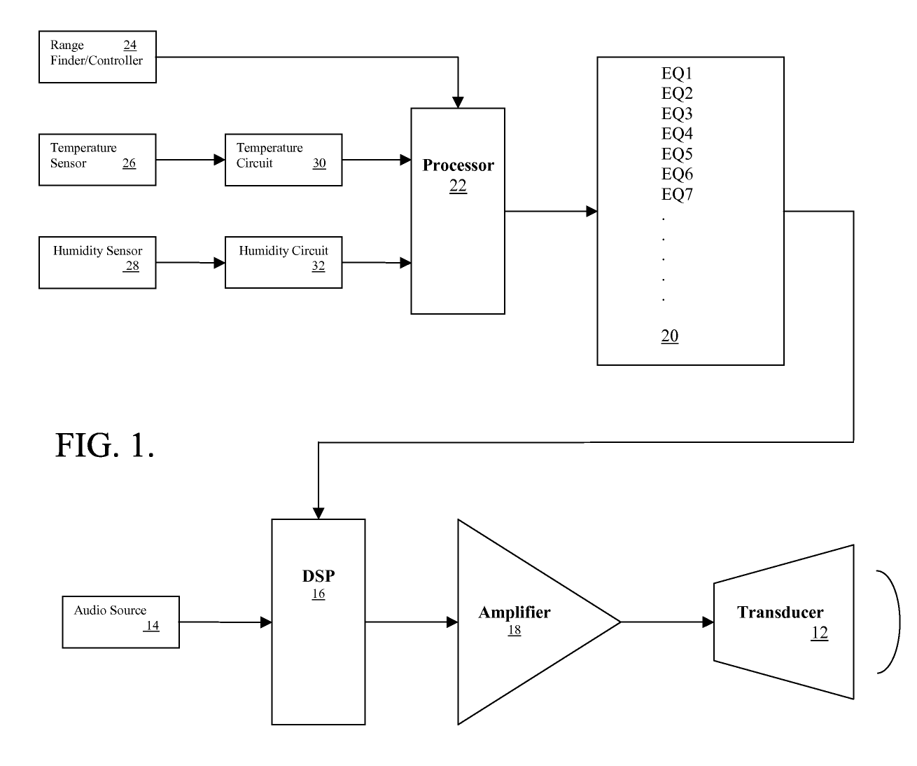

Referring to FIG. 1, a system 10 includes a transducer 12, such as a loudspeaker, that converts electrical signals into audible sound waves. An original source 14 of an audio signal is coupled to the transducer 12. The source 14 is typically a microphone or a device storing audio information, such as a CD, MP3 or tape player.

Signals from the source 14 are processed by a digital signal processor (DSP) 16. The DSP 16 modifies the frequency profile of the signal from the source 14 and inputs the modified signal to an amplifier 18, which generates an amplified signal input to the transducer 12.

The DSP 16 modifies the signal to compensate for environmental conditions and the distance the sound waves emitted by the transducer 12 will travel. In one embodiment, the DSP 16 uses a plurality of equalization tables (EQ1, EQ2 . . . EQi) stored in a database 20. The equalization tables store multipliers corresponding to a frequency or band of frequencies within the audible range of sound waves. The multipliers describe how much the intensity of a sound wave must be amplified at a given frequency in order to compensate for frequency dependent attenuation as the sound wave travels through air. In one embodiment, equalization tables have a form similar to Table 1 below.

TABLE 1
Equalization Table

| Frequency | Multiplier |
|---|---|
| f₁-f₂ Hz | M₁₂ |
| f₂-f₃ Hz | M₂₃ |
| . | . |
| . | . |
| . | . |
| fᵢ-fⱼ Hz | Mᵢⱼ |

The values for the multipliers are calculated according to known principles of sound propagation in air. The attenuation of sound in air due to viscous, thermal and rotational loss mechanisms is proportional to f². However, losses due to vibrational relaxation of oxygen molecules are generally much greater than those due to the classical processes, and the attenuation of sound varies significantly with temperature, water-vapor content and frequency. A method for calculating the absorption at a given temperature, humidity and pressure can be found in ISO 9613-1 (1993). The table gives values of attenuation in dB km⁻¹ for a temperature of 20° C. and a pressure of 101.325 kPa. The uncertainty is estimated to be±10%.

Values used to calculate the attenuation of sound waves in air include:

| | |
|---|---|
| Pa | Ambient atmospheric pressure in kPa |
| Pr | Reference ambient atmospheric pressure: 101.325 kPa |
| Psat | Saturation vapor pressure ca equal: |
| | International Meteorological Tables WMO-No. 188 TP94 |
| | World Meteorological Organization - Geneva Switzerland |
| T | Ambient atmospheric temperature in K (Kelvin): |
| | K = 273.15 + Temperature in ° C. (by US known as centigrade, |
| | Europe as Celsius) |
| To | Reference temperature in K: 293.15 K (20° C.) |
| Tol | Triple-point isotherm temp: 273.16 K = 273.15 + 0.01 K |
| | (0.01° C.) |
| H | Molar concentration of water vapor, as a percentage |
| HR | Relative humidity as a percentage |
| f | Frequency |
| frO | Oxygen relaxation frequency |
| frN | Nitrogen relaxation frequency |

The equalization tables each correspond to multipliers substantially compensating for attenuation that occurs at a value or range of values of one or more sensed environmental condition such as temperature, humidity or other environmental conditions such as ambient atmospheric pressure. In embodiments where equalization tables compensate for more than one environmental condition, each equalization table corresponds to a unique combination of environmental conditions or a unique combination of ranges or values for each environmental condition.

For example, the range of likely temperature may be divided into a plurality of subranges represented as values T₁, T₂, . . . Tᵢ, . . . Tₙ and the range of possible humidity may be divided into subranges represented as H₁, H₂, . . . Hⱼ, . . . Hₙ. An equalization table may be provided for each of a plurality of unique combinations Tᵢ and Hⱼ. In a similar fashion, the range of likely ambient pressure may be represented by a series of subranges P₁, P₂, . . . Pₖ, . . . Pₙ. Where ambient pressure is considered, an equalization table may be provided for each of a plurality of unique combinations Tᵢ, Hⱼ and Pₖ.

In an alternative embodiment, the equalization tables are replaced by an equation describing the desired frequency profile as a function of frequency (f). Accordingly, an equation gᵢⱼₖ(f) may be provided for each of a plurality of unique combinations of subranges Tᵢ, Hⱼ and Pₖ of one or more environmental conditions.

In an additional alternative embodiment, the equalization tables are replaced by a multivariable equation, function or algorithm: g_{T,H,P}(f) describing the desired frequency profile as a function of frequency (f) and one or more environmental variables of temperature (T), humidity (H) and pressure (P). The function g_{T,H,P}(f) may evaluate to a real or imaginary number that may have a continuous or a discrete number of values. The variables f, T, H, and P may be a real number and have a continuous or a discrete number of values.

In certain embodiments, the equalization tables also compensate for the distance that sound will travel. The further sound travels, the greater the impact of frequency dependent attenuation. Accordingly, equalization tables for each combination of subranges of the environmental conditions may be provided for a plurality of distances D₁, D₂, . . . Dⱼ, . . . Dₙ. In certain embodiments, simple range divisions may be used, for example, near and far ranges. In such embodiments, only two sets of equalization tables for each combination of subranges of the environmental conditions need be provided. For example, the near range may be defined as a distance of less than 400 yards and the far range as a distance of 400 yards or more.

In the preferred embodiment, a user provides an input indicating the desired range. Various types of user input devices may be incorporated into the present system. For example, the system may provide a dial, discrete buttons each corresponding to a range of distances, a number pad, touch screen, or the like, enabling a user to input the range. In some embodiments, a range finder using a laser, radar, or like means, is used to determine the range.

The use of any one parameter including temperature, humidity, pressure and range is optional. Alternative embodiments of the invention may use less than all of these parameters. In systems not mapping equalization tables to all of these parameters, a typical or known value for the unused parameter may be considered to calculate the equalization tables. For example, where the expected distance is known, the equalization tables compensates for attenuation that is likely to occur for the known distance across a range of environmental conditions such as temperature, humidity and/or pressure.

With reference again to FIG. 1, in the preferred embodiment, the equalization table used by the DSP 16 is selected by a processor 22 that receives inputs from a range finder/controller 24, a temperature sensor 26 and a humidity sensor 28. The range finder/controller may permit a user to input the value for the range. The range finder may also automatically determine a range. In the preferred embodiment, the range finder is omitted and a user manually indicates a range. The humidity sensor may include any humidity sensor known in the art, such as a resistive, capacitive, thermal conduction or infrared humidity sensor. The outputs of the temperature sensor 26 and humidity sensor 28 may be conditioned by a temperature circuit 30 and a humidity circuit 32, respectively. The temperature and humidity circuits 30, 32 convert a signal from the sensors 26, 28 into a form readable by the processor 22. The circuits 30, 32 may therefore scale the output, remove noise, or convert the output to a digital signal. In embodiments using ambient pressure to select an equalization table, a pressure sensor and a corresponding signal conditioning circuit may provide an input to the processor 22.

In the preferred embodiment, the processor 22 receives the inputs from the sensors 26, 28 and determines which of the equalization tables in a database 20 corresponds thereto. The processor 22 and DSP 16 may be modules of the same program or processor chip. Alternatively, the processor 22 and DSP 16 may be separate software applications or distinct processor chips.

The components of the system 10 illustrated in FIG. 1 may be discrete components. Alternatively, the functionality of two or more of the illustrated components may be combined in a single device providing equivalent functionality. For example, the functionality of the processor 22, database 20 and DSP 16 may be incorporated in a single processing chip or a single application executed by a general purpose computer chip. In embodiments where less than all of the distance, temperature and humidity factors are used, the structure used to input these parameters to the processor 22 may be omitted. For example, in embodiments where the distance is known or assumed, the range finder/controller may be omitted. In embodiments where ambient pressure is used to select the equalization table, the system of FIG. 1 may further include additional components necessary to determine ambient pressure, preferably controlled by the processor 22.

In other embodiments, different configurations may be used, such as systems that implement analog, digital or a hybrid of analog and digital components (e.g. processor controlled digital potentiometers that control an analog equalizer). Also, the processor 22 and the DSP 16 may be the same device.

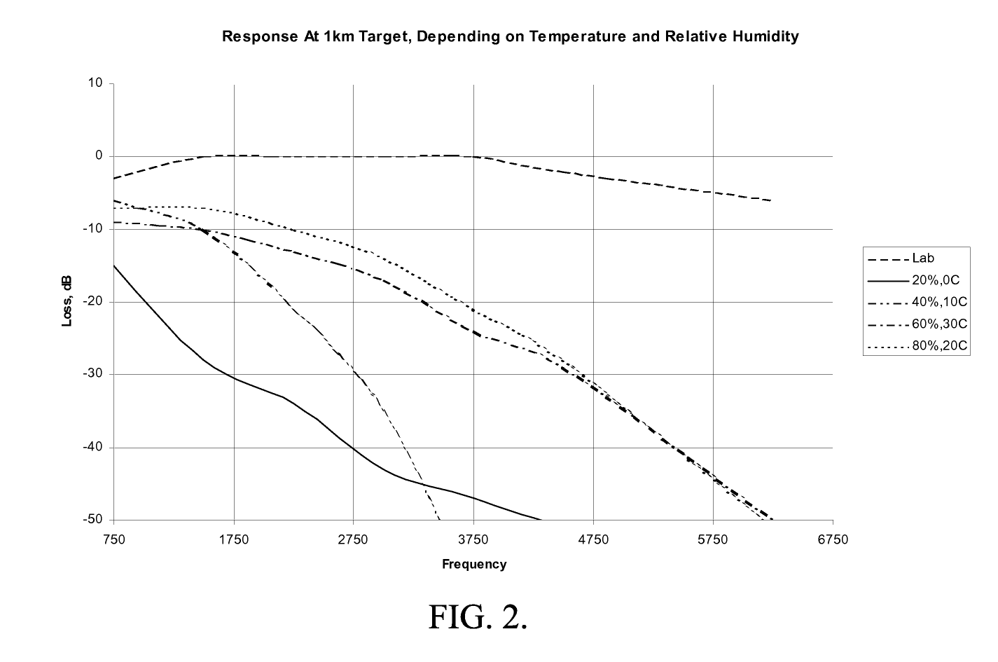

Referring to FIG. 2, the phenomenon for which the system 10 compensates is evident in the plot lines corresponding to different temperatures and humidities. Particularly at high frequencies, the amount of attenuation over a one kilometer distance is extremely temperature and humidity dependent. Equalization curves corresponding to the temperatures and humidities corresponding to the plot lines would, therefore, boost higher frequencies according to the anticipated attenuation.

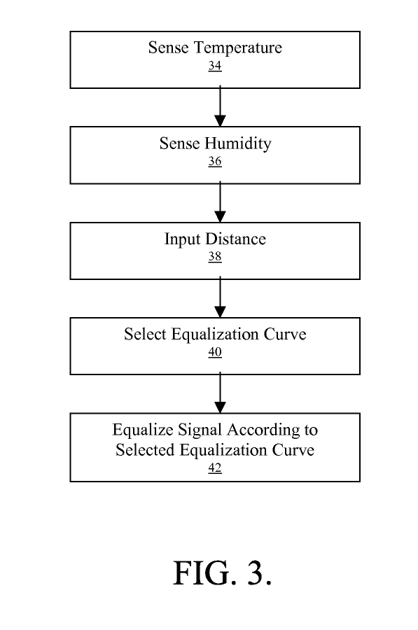

Referring to FIG. 3, a method for using the system 10 may include sensing the temperature at block 34 and sensing the humidity at block 36. Sensing the temperature at block 24 may include use of one or more thermistors in an analog tone control circuit to change the frequency response of the system 10 in response to a temperature change to compensate for temperature dependent attenuation in air. In the preferred embodiment, the temperature is sensed at block 24 and the sensed value is used to select an equalization table.

The anticipated or desired distance that the sound will travel is input at block 38. At block 40 the equalization table corresponding to the conditions determined at blocks 34, 36 and 38 is selected. At block 42, audio signals from the audio source 14 are equalized according to the compensation information obtained from the equalization table selected at block 40. In embodiments where ambient pressure is used to select the equalization table the method of FIG. 3 may further include sensing the pressure.

In an alternate embodiment, the processor 22/DSP 16 analyzes the frequency spectrum of the output from the audio source 14 and adjusts the equalizer settings (power supplied to frequencies in the spectrum) based on the analysis. For example, if the output from the audio source 14 is below a predefined threshold in a certain frequency range, the system reduces or does not increase power to that frequency range in the amplifier even if analysis of the environmental conditions indicates an increase is warranted.

In another embodiment, the capabilities of the amplifier are taken into consideration before the audio signal is altered. The degree of frequency response modification is varied according the amplifier power that is available. For example, the solution determined at a particular RH, T, and range may call for a 41 dB boost at 4 kHz. If only 25 dB of amplifier headroom is available at that time, the system will limit the amount of boost to 25 dB to avoid distortion and/or amplifier overload.

While the preferred embodiment of the invention has been illustrated and described, as noted above, many changes can be made without departing from the spirit and scope of the invention. Accordingly, the scope of the invention is not limited by the disclosure of the preferred embodiment.

The embodiments of the invention in which an exclusive property or privilege is claimed are defined as follows:

1. An audio processing method comprising:
determining at least one of temperature, humidity, range to a target, or atmospheric pressure information; and
generating an audio signal based on the determined at least one temperature, humidity, range to a target, or atmospheric pressure information.

2. The method of claim 1, wherein generating comprises receiving an audio input signal and modifying the inputted signal based on the determined at least one temperature, humidity, range to a target, or atmospheric pressure information.

3. The method of claim 2, wherein generating further comprises analyzing the received audio input signal and modifying comprises modifying the inputted signal based on the analyzed audio input signal.

4. The method of claim 2, wherein modifying is further based on capabilities of an associated amplifier.

5. The method of claim 2, wherein generating is further based on two or more of temperature, humidity, range to a target, or atmospheric pressure information.

6. The method of claim 2, wherein modifying comprises modifying the frequency profile of the audio input signal.

7. An audio processing system comprising:
a sensor configured to determine at least one of temperature, humidity, range to a target, or atmospheric pressure information;
a processing device configured to generate an audio signal based on the determined at least one temperature, humidity, range to a target, or atmospheric pressure information; and
one or more speakers in signal communication with the processing device, the one or more speakers configured to output the generated audio signal.

8. The system of claim 7, further comprising an audio input device configured to send an unmodified audio signal to the processing device, wherein the processing device is configured to modify the unmodified audio signal based on the determined at least one temperature, humidity, range to a target, or atmospheric pressure information.

9. The system of claim 8, wherein the processing device analyzes the unmodified audio signal and modifies the unmodified audio signal based on the analysis.

10. The system of claim 8, wherein the processing device comprises an amplifier, the processing device modifies further based on capabilities of the amplifier.

11. The system of claim 8, wherein the processing device modifies further based on two or more of temperature, humidity, range to a target, or atmospheric pressure information.

12. The system of claim 8, wherein the processing device modifies the frequency profile of the audio input signal.
